(19) United States
(12) Patent Application Publication
(10) Pub. No.: US 2026/0073105 A1
(43) Pub. Date: Mar. 12, 2026

(54) FILE PROCESSING METHOD AND APPARATUS APPLIED TO EDA TOOL

(71) Applicant: SAMSUNG ELECTRONICS CO., LTD., SUWON-SI (KR)

(72) Inventors: Maoxin Shen, Xi'an (CN); Jaeho Jung, Suwon-si (KR); Youngjoo Kim, Suwon-si (KR); Penghui Zhang, Xi'an (CN); Guanqun Li, Xi'an (CN)

(21) Appl. No.: 18/921,763

(22) Filed: Oct. 21, 2024

(30) Foreign Application Priority Data
Sep. 6, 2024 (CN) 202411252279.2

(51) Int. Cl. G06F 30/31

(52) U.S. Cl. CPC G06F 30/31

(57) ABSTRACT

The present disclosure provides a file processing method and apparatus a, which may obtain a first electronic circuit design file, wherein the first electronic circuit design file has an XML format, the first electronic circuit design file is converted to a second electronic circuit design file having a JSON format based on a conversion rule associating a first XML tag corresponding to an electronic circuit design element with a JSON attribute corresponding to the same electronic circuit design element, and generate an electronic circuit design based on the second electronic circuit design file using an electronic design automation (EDA) tool.

### CROSS-REFERENCE TO RELATED APPLICATIONS

This application is based on and claims priority under 35 U.S.C. § 119 to Chinese Patent Application No. 202411252279.2 filed on Sep. 6, 2024 in the Chinese Intellectual Property Office, the contents of which are incorporated by reference herein in their entirety.

### TECHNICAL FIELD

The present disclosure relates to a field of System on Chip (SoC) design, and specifically to a file processing method and apparatus applied to an EDA tool, a storage medium, an electronic device and a system.

### BACKGROUND ART

Electronic Design Automation (EDA) tools are essential in the semiconductor industry, facilitating the design and verification of integrated circuits (ICs). The tools support various stages of the IC design process, including schematic capture, layout design, simulation, and verification. As semiconductor technology advances, the complexity and scale of IC designs have significantly increased, resulting in the generation of vast amounts of design data.

Existing file processing techniques are unable to manage and manipulate the data to ensure smooth design workflows and accurate results. Moreover, existing file processing techniques often struggle to keep pace with the growing demands, leading to bottlenecks and inefficiencies in the design process. Therefore, there is a need in the art for systems and methods that can accurately and efficiently perform file processing in case of an EDA tool.

### SUMMARY

The present disclosure provides a file processing method and apparatus applied to an EDA tool, a storage medium, an electric device and a system, to at least solve the above technical problem and other technical problems not mentioned above.

The present disclosure describes systems and methods for a file processing method applied to an EDA tool. Embodiments of the present disclosure may be configured to convert an IP-XACT file in an XML format to a JSON format based on a predetermined conversion rule. In some cases, the converted file in JSON format may be processed using the EDA tool. Subsequently, the processed JSON file may be reconverted to the XML format.

According to an aspect of the present disclosure, there is provided a method of electronic circuit design. The method includes: obtaining a first electronic circuit design file; wherein the first electronic circuit design file has an XML format, the first electronic circuit design file is converted to a second electronic circuit design file having a JSON format based on a conversion rule associating a first XML tag corresponding to an electronic circuit design element with a JSON attribute corresponding to the same electronic circuit design element; and generating, using an electronic design automation (EDA) tool, an electronic circuit design based on the second electronic circuit design file.

Additionally or alternatively, generating the first electronic circuit design file includes: performing a parsing operation on the second electronic circuit design file to generate a JSON object; performing an operation on the JSON object, wherein the operation includes at least one of creating, traversing, adding, deleting, and modifying.

Additionally or alternatively, generating the electronic circuit design further comprises: serializing the object to obtain a serialized electronic circuit design file and saving the serialized electronic circuit design file.

Additionally or alternatively, converting the first electronic circuit design file to the second electronic circuit design file comprises validating the first electronic circuit design file; parsing the validated first electronic circuit design file; converting, based on the conversion rule, the first electronic circuit design file to obtain a JSON object; and serializing the JSON object to obtain the second electronic circuit design file.

Additionally or alternatively, the method further includes validating the second electronic circuit design file; parsing the validated second electronic circuit design file; converting, based on the conversion rule, the second electronic circuit design file to obtain an XML object; and serializing the XML object to obtain a third electronic circuit design file.

Additionally or alternatively, the predetermined conversion rule maintains semantic consistency.

Additionally or alternatively, the generating the electronic circuit design includes: verifying a validity of the first electronic circuit design file based on a predetermined validation module; wherein the predetermined validation module includes a predefined rule and a predefined constraint, each of the predefined rule and constraint being specific to the first electronic circuit design file.

According to another aspect of the present disclosure, there is provided an apparatus for electronic circuit design. The apparatus includes: a file acquisition module configured to obtain a first electronic circuit design file; wherein the first electronic circuit design file has an XML format, a conversion module configured to convert the first electronic circuit design file to a second electronic circuit design file having a JSON format based on a conversion rule associating a first XML tag corresponding to an electronic circuit design element with a JSON attribute corresponding to the same electronic circuit design element; and a file process module configured to generate an electronic circuit design based on the second electronic circuit design file.

Additionally or alternatively, the file process module is configured to perform a parsing operation on the second electronic circuit design file to generate a JSON object; perform an operation on the JSON object, wherein the operation includes at least one of creating, traversing, adding, deleting, and modifying.

Additionally or alternatively, the file process module is further configured to serialize the object to obtain a serialized electronic circuit design file and save the serialized electronic circuit design file.

Additionally or alternatively, the conversion module is further configured to validate the first electronic circuit design file, parse the validated first electronic circuit design file, convert, based on the conversion rule, the first electronic circuit design file to obtain a JSON object, and serialize the JSON object to obtain the second electronic circuit design file.

Additionally or alternatively, the apparatus further includes a conversion module configured to: validate the second electronic circuit design file, parse the validated second electronic circuit design file, convert, based on the conversion rule, the second electronic circuit design file to obtain an XML object, and serialize the XML object to obtain a third electronic circuit design file.

Additionally or alternatively, the predetermined conversion rule maintains semantic consistency.

Additionally or alternatively, the file process module is further configured to verify a validity of the first electronic circuit design file based on a predetermined validation module; wherein the predetermined validation module includes a predefined rule and a predefined constraint, each of the predefined rule and constraint being specific to the first electronic circuit design file.

According to another aspect of the present disclosure, there is provided an electronic device. The electronic device includes: at least one processor; at least one memory storing computer-executable instructions, wherein the computer-executable instructions, when run by the at least one processor, cause the at least one processor to perform a file processing method applied to an EDA tool as described herein.

According to another aspect of the present disclosure, there is provided a computer readable storage medium storing instructions, wherein the instructions, when run by at least one computing apparatus, cause the at least one computing apparatus to perform a file processing method applied to an EDA tool as described herein.

According to another aspect of the present disclosure, there is provided a system including at least one computing apparatus and at least one storage apparatus storing instructions, wherein the instructions, when run by the at least one computing apparatus, cause the at least one computing apparatus to perform a file processing method applied to an EDA tool as described herein.

The technical solutions provided by the present disclosure have at least the following beneficial effects.

The file processing method and apparatus applied to an EDA tool, the storage medium, the electronic device, and the system provided by the present disclosure enable the EDA tool to process a lightweight JavaScript Object Notation (JSON) file (i.e., instead of processing an IP-XACT XML file that uses high computational resources). Therefore, when there are a large number of IP-XACT XML files in the EDA tool, the negative impact on the performance of the EDA tool due to the processing of the XML files that may occupy a lot of memory and CPU resources is prevented.

Additionally, comparing a JSON object with an XML Document Object Model (DOM) object in a case that they contain same semantic information, the JSON object occupies much less memory resources than the XML DOM object. Therefore, accessing and maintaining content of the JSON object is significantly simpler and more flexible than accessing and maintaining content of the XML DOM.

Additionally, the predefined conversion rule may be used to easily and quickly convert an IP-XACT file in JSON format and an IP-XACT file in XML format.

### BRIEF DESCRIPTION OF THE DRAWINGS

The accompanying drawings herein, which are incorporated into and form a part of the specification, illustrate embodiments consistent with the present disclosure and are used in conjunction with the specification to explain the principles of the present disclosure and do not constitute an undue limitation of the present disclosure.

FIG. 1 illustrates a flowchart of a file processing method applied to an EDA tool according to an exemplary embodiment of the present disclosure;

FIG. 2 illustrates a flowchart for converting a first electronic circuit design file to a second electronic circuit design file according to an exemplary embodiment of the present disclosure;

FIG. 3 illustrates a flowchart for processing a second electronic circuit design file by an EDA tool according to an exemplary embodiment of the present disclosure;

FIG. 4 illustrates a flowchart for converting a second electronic circuit design file to the first electronic circuit design file according to an exemplary embodiment of the present disclosure;

FIG. 5 illustrates a schematic diagram of a file conversion tool according to an exemplary embodiment of the present disclosure;

FIG. 6 is a block diagram of a file processing apparatus applied to an EDA tool according to an exemplary embodiment of the present disclosure;

FIG. 7 is a block diagram of an electronic device according to an exemplary embodiment of the present disclosure.

### DETAILED DESCRIPTION

The rapid evolution of IC designs presents several challenges for existing EDA tools, particularly in the area of file processing. As design files grow in size and complexity, traditional file processing methods become inadequate, leading to increased processing times and higher computational resource requirements. Additionally, the diverse range of data formats and standards in the industry complicates the integration and interoperability of various EDA tools. There is a need for a more efficient and flexible file processing method and apparatus that can handle large-scale design files, support multiple data formats, and optimize resource utilization.

IP-XACT is a standard for describing Intellectual Property (IP). In some cases, the IP-XACT standard may be used to provide a uniform specification of metadata for EDA, semiconductors, and electronic design IP vendors. For example, the IP-XACT standard may be widely used in a SoC design domain. In some examples, an EDA software at SoC integration phases may include functions to parse an IP-XACT file, manipulate IP-XACT data, and save the IP-XACT file.

In some cases, a SoC project may include a large number of IP-XACT files based on an extensible Markup Language (XML) format. Additionally, parsing and maintaining the IP-XACT files may use a large amount of memory and Central Processing Unit (CPU) resources which may negatively impact the performance of an EDA program.

The present disclosure describes systems and methods for a file processing method applied to an EDA tool. Embodiments of the present disclosure may be configured to convert an IP-XACT file in an XML format to a JSON format based on a predetermined conversion rule. In some cases, the converted file in JSON format may be processed using the EDA tool. Subsequently, the processed JSON file may be reconverted to the XML format.

According to an embodiment of the present disclosure, an IP-XACT file may be acquired in a JSON format. In some cases, the acquisition may be performed based on converting an IP-XACT file in XML format using a predefined conversion rule. In some examples, the predefined conversion rule may be configured to ensure semantic consistency between the IP-XACT file in XML format and the IP-XACT file in JSON format.

An embodiment of the present disclosure may be configured to perform a processing of the IP-XACT file in JSON format. In some cases, the processing of the JSON file may include a validation to ensure the IP-XACT file in JSON format conforms to the rules and constraints based on a schema definition (JSON Schema Definition). Subsequently, the validated file is parsed to obtain a JSON object. In some cases, an operation may be performed on the JSON object based on business logic and saved to a JSON file.

According to an embodiment of the present disclosure, the saved JSON file may be reconverted to the IP-XACT file in XML format. In some cases, the conversion process may be performed using a predefined rule to ensure semantic consistency, i.e., the converted file may have the same semantics as the original IP-XACT file in XML format.

Embodiments of the present disclosure are configured to provide a method of electronic circuit design. In some cases, the method comprises obtaining a first electronic circuit design file, wherein the first electronic circuit design file has an XML format. In some cases, the first electronic circuit design file may be converted to a second electronic circuit design file having a JSON format based on a conversion rule associating a first XML tag corresponding to an electronic circuit design element with a JSON attribute corresponding to the same electronic circuit design element. An electronic design automation (EDA) tool may be used to generate an electronic circuit design based on the second electronic circuit design file.

Accordingly, by converting an IP-XACT file in XML format to a JSON format, embodiments of the present disclosure are able to process the IP-XACT file with significantly reduced resources (e.g., memory consumption, processing time, etc.). Additionally, by converting the IP-XACT file to a JSON format, embodiments ensure the processes of reading and parsing of the JSON file may be performed by multiple programming languages (e.g., Java, Python, etc.).

In order to enable a person of ordinary skill in the art to better understand technical solutions of the present disclosure, the technical solutions in the embodiments of the present disclosure will be described clearly and completely in the following, in conjunction with the accompanying drawings.

It is noted that terms “first”, “second” and the like in the specification and claims of the present disclosure and the above accompanying drawings are used for distinguishing similar objects, and need not to be used for describing a particular order or sequence. It should be understood that data so used may be interchanged, where appropriate, so that the embodiments of the present disclosure described herein may be implemented in an order other than those illustrated or described herein. The embodiments described in the following embodiments do not represent all embodiments consistent with the present disclosure. Rather, they are only examples of apparatuses and methods consistent with some aspects of the present disclosure as detailed in the appended claims.

It is noted herein that a phrase “at least one of several items” as it appears in the present disclosure is intended to encompass three parallel cases of “any one of the several items”, “a combination of any number of the several items”, and “all of the several items”. For example, “including at least one of A and B” includes the following three parallel cases: (1) including A; (2) including B; and (3) including A and B. Another example is “performing at least one of step 1 and step 2”, which represents the following three parallel cases: (1) performing step one; (2) performing step two; and (3) performing step one and step two.

Existing technologies comprise many EDA software at SoC integration phases that include functions to parse an IP-XACT file in XML format, manipulate IP-XACT data, and save the IP-XACT file. In case of SoC integration design, an IP may be packaged as a component (including configuration information) in IP-XACT, wherein the IP may be a configurable IP. In case of an EDA tool, the component may be instantiated by setting different parameter values.

IP-XACT is based on an XML format. In some cases, there may be two XML parsers, i.e., a Document Object Model (DOM) parser and a Simple API for XML Parsing (SAX) parser. In some cases, the SAX parser may not be used in the EDA tool since the SAX parser may not support writing an XML file.

An XML DOM may define a standard set of methods for accessing and maintaining XML documents. In case of parsing an XML file, the DOM parser constructs a DOM tree in a memory, and each node in the DOM tree may represent a node in the XML file. In some cases, a scripting language (e.g., JavaScript, etc.) may be used to access and manipulate each node in the file via the DOM. Additionally, each DOM node may contain a large amount of information, such that the DOM tree may occupy a high memory space. Program developers may access the nodes in the DOM tree through an XML Path Language (XPath).

In case of a SoC project, presence of a large number of IP-XACT XML files may have a negative impact on the performance of an EDA program since the parsing and maintaining of the files may use a large amount of memory and CPU resources. As the complexity of the SoC design increases, the number of IP-XACT files included in one SoC project may also increase, and the resource consumption and the performance problem caused by parsing and maintaining IP-XACT files may become more serious.

Accordingly, the present disclosure provides a file processing method and apparatus applied to an EDA tool, a storage medium, an electronic device, and a system, which enable the EDA tool to no longer directly process an IP-XACT XML file. In some cases, embodiments may process a lightweight JSON file, such that in case of a large number of IP-XACT XML files in the EDA tool, the performance of the EDA tool due to the file processing occupying a large amount of memory and CPU resources is significantly reduced.

Compared with an XML format, a file in JSON format is lightweight and easy to read. Additionally, most programming languages (Javascript, python, java, etc.) include methods to parse and serialize a JSON file. That is, accessing and maintaining content of a JSON object is much simpler and more flexible than the content of an XML DOM. Comparing a JSON object with an XML DOM object in a case that each of the JSON object and the XML DOM object may contain same semantic information, the JSON object may occupy much less memory resources than the XML DOM object. Therefore, developing JSON-based applications is easier than XML-based applications.

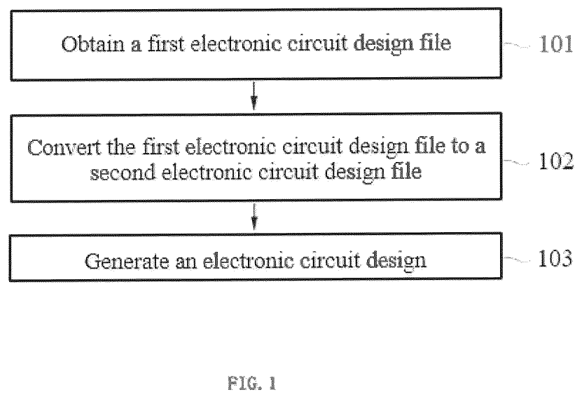

The present disclosure describes a file processing method applied to an EDA tool, an apparatus, a storage medium, an electronic device and a system with reference to FIGS. 1 through 7.

FIG. 1 is a flowchart of a file processing method applied to an EDA tool according to an exemplary embodiment of the present application.

Referring to FIG. 1, at step 101, a first electronic circuit design file may be acquired. The first electronic circuit design file is an IP-XACT file in XML format. At step 102, the first electronic circuit design file may be converted to a second electronic circuit design file, and the second electronic circuit design file is an IP-XACT file in JSON format.

In some cases, an IP-XACT file in XML format is a standardized file format defined by the IEEE 1685 standard. The IP-XACT file in XML format is used to describe and store metadata about electronic components, particularly IP (intellectual property) blocks, which are reusable units of logic, chip design, or other components used in system-on-chip (SoC) design. The XML format provides for a structured, machine-readable representation of the data, enabling automation and interoperability between different design and verification tools.

In some examples, an IP-XACT XML file consists of several key sections, each encapsulating specific types of information about the IP block, such as general information about the IP block, such as its name, version, and vendor; description of the interfaces that the IP block provides for communication with other components (e.g., type of bus, protocol, and the direction of the interface (e.g., master, slave)); lists of the ports (i.e., inputs and outputs) of the IP block, including names, directions, and data types; memory layout associated with the IP block, including address spaces, address blocks, and registers; configurable parameters for the IP block, which can be set to customize behavior; files associated with the IP block, such as source code, documentation, and scripts; and additional, vendor-specific information that extends beyond the standard schema.

Additionally, an IP-XACT file in JSON format refers to a representation of IP-XACT data using the JSON (JavaScript Object Notation) format. IP-XACT is used to describe and handle electronic components and the corresponding metadata, particularly in the context of system-on-chip (SoC) designs. In some examples, IP-XACT defines XML schemas for capturing the structure and configuration of intellectual property (IP) blocks, making it easier to integrate and automate various design tools.

In case of the JSON format, an IP-XACT file may include similar information but structured using JSON's syntax. For example, the IP-XACT file may include information about the IP component, such as its name, version, and vendor; specification of the interfaces, including the protocols and signals used; descriptions of memory layouts, including registers and address spaces; configurable parameters for the IP block; and information regarding files associated with the component, such as source files, documentation, and scripts. In some examples, use of JSON may make the IP-XACT file easier to integrate with web-based tools and services or to exchange data in a lightweight, human-readable format.

According to an exemplary embodiment of the present disclosure, an IP-XACT file in JSON format may be acquired. In some cases, the acquired IP-XACT file in JSON format may be generated directly from what a file needs to describe. However, embodiments may not be limited thereto.

According to an exemplary embodiment of the present disclosure, the second electronic circuit design file may be obtained by converting the first electronic circuit design file based on a predetermined conversion rule. For example, the second electronic circuit design file is an IP-XACT file in JSON format.

According to an exemplary embodiment of the present disclosure, an IP-XACT file in JSON format may be obtained by converting an existing IP-XACT file in XML format based on a predetermined conversion rule.

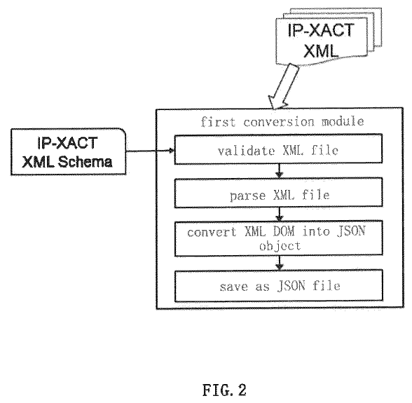

According to an exemplary embodiment of the present disclosure, the obtaining the second electronic circuit design file by converting the first electronic circuit design file based on the predetermined conversion rule may include: obtaining the second electronic circuit design file by validating, parsing, converting based on the predetermined conversion rule, and serializing and saving the first electronic circuit design file. Further details regarding the conversion process are provided with reference to FIG. 2.

FIG. 2 illustrates a flowchart for converting a first electronic circuit design file, according to an exemplary embodiment of the present disclosure.

Referring to FIG. 2, an existing IP-XACT file in XML format may be converted. In some cases, a first conversion module includes a function for converting the existing IP-XACT file in XML format to obtain an IP-XACT file in JSON format. According to an embodiment, validity of the IP-XACT file in XML format may be validated by IP-XACT XML Schema Definition (XSD) during the conversion process.

In some cases, an IP-XACT XML Schema Definition (XSD) is a specification used to define the structure and elements of IP-XACT XML files, which describe electronic components in system-on-chip (SoC) designs. The XSD provides a standardized format that ensures consistency and interoperability across different electronic design automation (EDA) tools. In some cases, the XSD defines various components, including metadata, bus interfaces, ports, memory maps, parameters, and file sets. By adhering to the XSD, IP-XACT files can be validated for accuracy, ensuring the files conform to the prescribed structure and data types. The standardization facilitates the automation of design, integration, and verification processes, enabling efficient IP management and seamless integration of IP blocks from different vendors. The IP-XACT XSD plays a crucial role in the semiconductor industry, supporting the reliable exchange and reuse of IP components in complex electronic systems.

According to an embodiment, a successful validation implies that the file meets a specific constraint. In some examples, the file may be parsed to get an XML DOM. In some examples, the XML DOM may be converted into a JSON object based on a predetermined conversion rule. Additionally, the JSON object may be serialized and saved as the IP-XACT file in JSON format which completes the conversion of the IP-XACT file in XML format to the IP-XACT file in JSON format.

Referring again to FIG. 1, at step 103, the second electronic circuit design file may be processed.

According to an exemplary embodiment of the present disclosure, processing the second electronic circuit design file may include validating or verifying a validity of the second electronic circuit design file based on a predetermined validation module. In some cases, the predetermined validation module may include a predefined rule and constraint, the rule and constraint being specific to the second file.

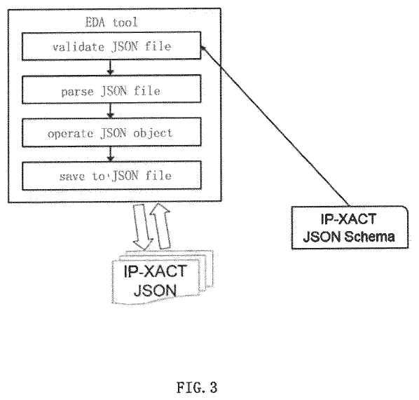

FIG. 3 illustrates a flowchart for processing a second electronic circuit design file by an EDA tool of an exemplary embodiment of the present disclosure.

Referring to FIG. 3, according to an exemplary embodiment of the present disclosure, a predetermined validation module is configured to verify (e.g., validate) the validity on an acquired IP-XACT file in JSON format. In some cases, the validity validation/verification may be performed to ensure that the acquired file conforms to a predetermined rule and constraint.

For example, IP-XACT JSON Schema Definition may be defined as the predetermined validation module to validate a relationship between a type, a format and a key-value pair of data in an IP-XACT file in JSON format, and whether integrity of the data, etc. conforms to the predetermined rule and constraint, which ensures the reliability and availability of the data in the file.

An IP-XACT JSON Schema Definition (JSD) refer to a specification that defines the structure and elements of IP-XACT data represented in JSON format. The schema standardizes how electronic components, such as intellectual property (IP) blocks used in system-on-chip (SoC) designs, are described and documented. The JSD outlines the expected structure of JSON files, including key components such as metadata, bus interfaces, ports, memory maps, parameters, and associated files. By adhering to the JSD, IP-XACT JSON files can be validated for consistency and correctness, ensuring the files meet the required format and data types. The standardization facilitates the integration, automation, and verification of IP components across various electronic design automation (EDA) tools. The IP-XACT JSD enables seamless interoperability and data exchange, promoting efficient IP management and reuse within the semiconductor industry.

Specifically, for example, in an IP-XACT file in JSON format, component elements may include “vendor”, “library”, “name”, “version” and other basic types of attributes. Additionally, in some cases, the component elements may include complex types of attributes such as “memoryMaps”. Accordingly, a corresponding Schema file may be defined as follows (JSD):

```
{
“$schema”: “http://json-schema.org/draft-07/schema#”,
“$id”: “schemas/Component”,
“type”: “object”,
“properties”:{
  “vendor”: {“type”: “string”},
  “library”: {“type”: “string”},
  “name”: {“type”: “string”},
  “version”: {“type”: “string”},
  “memoryMaps”: {“type”: “array”, “items”: {“$ref”: “MemoryMap”}},
  },
“required”:[“vendor”, “library”, “name”, “version”]
}
```

$schema: represents a used schema version
$id: represents basic URI
$type: represents a corresponding JSON data type
properties: represents attributes that an object contains (including optional and mandatory attributes)
required: represents attributes that must be included

In some cases, the attributes that may be missing from the component elements, i.e., whether the attribute type is correct, whether the attribute name is correct, etc. in the IP-XACT file in JSON format may be validated by the corresponding schema file. Moreover, each programming language may include a corresponding library to validate the JSON file according to schema, such as “ajv” of JavaScript, “jsonschema” of Python, etc., which may be chosen according to a specific usage scenario.

According to an exemplary embodiment of the present disclosure, the processing the second electronic circuit design file may include parsing the second electronic circuit design file to obtain a JSON object and performing a corresponding operation on the JSON object based on business logic. In some cases, the operation includes at least one of creating, traversing, adding, deleting, and modifying the JSON object.

According to an exemplary embodiment of the present disclosure, the EDA tool may load the acquired IP-XACT file in JSON format into a memory of an EDA program and parse it to obtain the JSON object. Additionally, the EDA tool may perform the corresponding operation on the JSON object based on the business logic. In some cases, the corresponding operation includes, but is not limited to, at least one of: creating, traversing, adding, deleting, and modifying the JSON object. That is, an operation of content of each node in the IP-XACT file in the JSON-format may be completed based on the operation of the JSON object, thereby realizing dynamic modification of content, a style, and a structure, etc., of the IP-XACT file in JSON format.

It can be understood that a certain user operation may be converted into the business logic, or the business logic may be generated based on a back-end of the EDA tool, etc.

According to an exemplary embodiment of the present disclosure, some JSON objects may be represented as follows:

```
{
“ports”:[{
  “name”:“port_A”,
  “direction”:“in”
}]
}
```

According to an exemplary embodiment of the present disclosure, the operation of the JSON object based on the business logic may be referred to the following examples.

For example, a “port” with a name “port_B” may be added to the JSON object based on the business logic and a direction of the added “port” may be set to “out” based on the business logic:

```
{
“ports”:[{
      “name”:“port_A”,
  “direction”:“in”
},{
    “name”:“port_B”,
      “direction”:“out”
}]
}
```

According to an exemplary embodiment of the present disclosure, the processing the second electronic circuit design file may further include saving the second electronic circuit design file obtained by serializing the JSON object.

In some cases, serializing a JSON object refers to the process of converting a JSON object into a string format that can be easily transmitted, stored, or shared. The serializing process includes encoding the structured data of a JSON object into a text-based representation. Serialization is essential for data exchange between systems or applications, as it provides for complex data structures to be transformed into a standardized format that can be understood and processed by different platforms. The resulting JSON string can then be deserialized back into a native data structure in the recipient system. The serialization process is widely used in web development, APIs, and data storage, facilitating the transfer and persistence of structured information.

According to an exemplary embodiment of the present disclosure, after the EDA tool completes the operation of the JSON object in the IP-XACT file in JSON format based on the business logic, the operated JSON object may be saved as a processed IP-XACT file in JSON format by serializing the JSON object.

According to an exemplary embodiment of the present disclosure, the processed second electronic circuit design file may be validated, parsed, converted based on a predetermined conversion rule, and serialized and saved to obtain a third electronic circuit design file. In some cases, the third electronic circuit design file is an IP-XACT file in XML format.

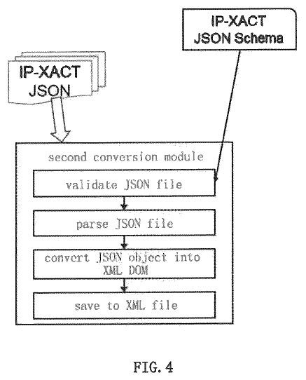

FIG. 4 illustrates a flowchart for converting a second electronic circuit design file of an exemplary embodiment of the present disclosure.

Referring to FIG. 4, according to an exemplary embodiment of the present disclosure, a function that may convert an IP-XACT file in JSON format to an IP-XACT file in XML format may be integrated into a second conversion module. In some cases, when the second conversion module may need to save an IP-XACT file in XML format, the processed IP-XACT file in JSON format may be validated, parsed, converted based on a predetermined conversion rule, and serialized and saved to obtain the IP-XACT file in XML format processed by the EDA tool of the present disclosure. Note that the validation of the IP-XACT file in JSON format may be performed using the predetermined validation module described herein. Additionally, the parsing, serializing, and saving of the IP-XACT file in JSON format may be performed using a parsing, serializing, and saving method in any programming language.

According to an exemplary embodiment of the present disclosure, when a downstream of the EDA tool is a third-party EDA tool, the system may output an IP-XACT XML file for use by the third-party EDA tool. In some examples, the third-party EDA tool is only capable of recognizing an IP-XACT files in XML format but not JSON Schema (JSD) of the present disclosure.

According to an exemplary embodiment of the present disclosure, a predetermined conversion rule may be used to maintain semantic consistency.

According to an exemplary embodiment of the present disclosure, a conversion may be performed based on a predetermined conversion rule to maintain semantic consistency between the IP-XACT file in XML format and the IP-XACT file in JSON format (e.g., when converting between an IP-XACT file in XML format and an IP-XACT file in JSON format). Specifically, the predetermined conversion rule may be used to define a corresponding relationship between semantically identical program statements in different program languages, for example, the corresponding relationship between semantically identical program statements in the IP-XACT file in XML format and the IP-XACT file in JSON format may be formed as shown in Table 1.

TABLE 1
Examples of the corresponding statements
between different program languages

| IP-XACT file in XML format | IP-XACT file in JSON format |
|---|---|
| <spirit:vendor>vendor_A</spirit:vendor> | {“vendor”:“vendor_A”} |
| <spirit:library>lib_A</spirit:library> | {“library”:“lib_A”} |

According to an exemplary embodiment of the present disclosure, the system may ensure, by the predetermined conversion rule, that an IP-XACT file in JSON format or an IP-XACT file in XML format obtained by conversion may have the same semantics as an original file, such that the same semantics may be obtained when processing a file based on the IP-XACT file in JSON format or when transmitting the IP-XACT file in XML format to a downstream tool for processing.

Note that each of the first electronic circuit design file and the third electronic circuit design file described herein are IP-XACT files in XML format. In some cases, the first electronic circuit design file and the third electronic circuit design file may be the same or different when the conversion between the IP-XACT file in JSON format and the IP-XACT file in XML format may be performed.

According to an exemplary embodiment of the present disclosure, the predetermined conversion rule may include a data cleaning and repairing rule for cleaning and repairing errors, deletions in data of a file before conversion, and inconsistent portions in the file before and after conversion to ensure the quality and accuracy of the data of the file. For example, duplicate data records may be deleted, missing data may be filled, and format errors may be corrected, etc.

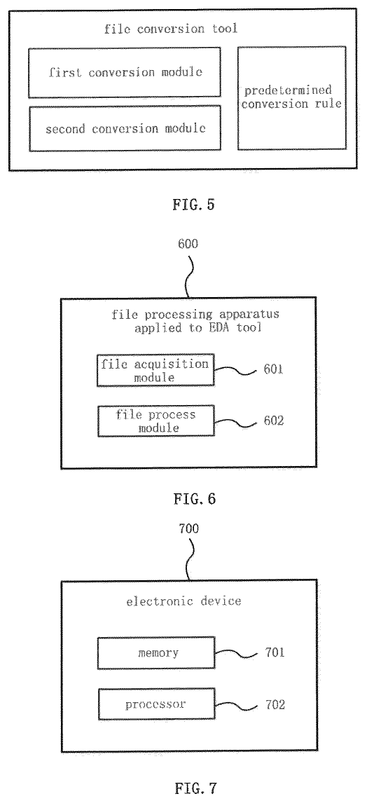

FIG. 5 illustrates a schematic diagram of a file conversion tool of an exemplary embodiment of the present disclosure.

Referring to FIG. 5, according to an exemplary embodiment of the present disclosure, the file conversion function may be packaged into a file conversion tool. Additionally, the file conversion tool may integrate a first conversion module for converting an IP-XACT file in XML format to an IP-XACT file in JSON format, a second conversion module for converting the IP-XACT file in JSON format to the IP-XACT file in XML format, and a predetermined conversion rule, on which the first conversion module and the second conversion module are jointly based, to realize the conversion between the IP-XACT file in XML format and the IP-XACT file in the JSON format.

According to an exemplary embodiment of the present disclosure, a test program may be written using Node.js. In case of a test including a file parsing function, parsing of an IP-XACT file in XML format and an IP-XACT file in JSON format may be tested.

After converting an IP-XACT XML file of 5.7 MB and an IP-XACT XML file of 78 MB into IP-XACT JSON files, test results show that parsing the file in JSON format may have a significant performance advantage in terms of parsing time, memory occupation, and serialization time.

TABLE 2
Comparison Test (1)

| | | | performance |
|---|---|---|---|
| | XML | JSON | comparison |
| file size | 5.7M | 9.7M | |
| Parsing time | 1046 ms | 38.5 ms | ↓96% |
| memory occupation | 79M | 18M | ↓77% |
| serialization time | 159.3 ms | 26 ms | ↓83% |

TABLE 3
Comparison Test (2)

| | | | performance |
|---|---|---|---|
| | XML | JSON | comparison |
| file size | 78M | 109M | |
| Parsing time | 10.3 s | 0.5 s | ↓95% |
| memory occupation | 1020M | 272M | ↓73% |
| serialization time | 2498.5 ms | 268.5 ms | ↓89% |

FIG. 6 is a block diagram of a file processing apparatus applied to an EDA tool according to an exemplary embodiment of the present application.

Referring to FIG. 6, the exemplary embodiment of the present application further provides a file processing apparatus 600 applied to an EDA tool, the apparatus 600 may include a file acquisition module 601 and a file process module 602.

The file acquisition module 601 may acquire a first electronic circuit design file; wherein the first electronic circuit design file is an IP-XACT file in XML format, the first electronic circuit design file is converted to a second electronic circuit design file, where the second electronic circuit design file is an IP-XACT file in JSON format.

The file process module 602 may process the second electronic circuit design file.

According to an exemplary embodiment of the present disclosure, the second electronic circuit design file may be obtained by validating, parsing, converting based on a predetermined conversion rule, and serializing and saving the first electronic circuit design file.

According to an exemplary embodiment of the present disclosure, the file process module 602 may validate validity of the second electronic circuit design file based on a predetermined validation module; wherein the predetermined validation module may include a predefined rule and constraint, the predefined rule and constraint being specific to the second electronic circuit design file.

According to an exemplary embodiment of the present disclosure, the file process module 602 may parse the second electronic circuit design file to obtain a JSON object; perform a corresponding operation on the JSON object based on business logic, wherein the operation includes at least one of creating, traversing, adding, deleting, and modifying.

According to an exemplary embodiment of the present disclosure, the file process module 602 may save the second electronic circuit design file obtained by serializing the JSON object.

According to an exemplary embodiment of the present disclosure, the file processing apparatus 600 applied to an EDA tool may further include a conversion module (not shown in FIG. 6), wherein the conversion module may validate, parse, convert based on the predetermined conversion rule and serialize and save the processed second electronic circuit design file to obtain a third electronic circuit design file, wherein the third electronic circuit design file is an IP-XACT file in XML format.

According to an exemplary embodiment of the present disclosure, the predetermined conversion rule may be used to maintain semantic consistency.

Note that the specific implementation process in the exemplary embodiment of the file processing apparatus 600 applied to an EDA tool may substantially be the same as that in the exemplary embodiment of the file processing method applied to an EDA tool. Repeated descriptions may be omitted herein.

The file processing apparatus 600 applied to an EDA tool may be configured as software, hardware, firmware, or any combination of the foregoing items for performing specific functions, respectively. For example, the apparatus may correspond to dedicated integrated circuits, pure software codes, or modules that combine software and hardware. Additionally, one or more of the functions implemented by the apparatuses may be uniformly performed by components in a physical entity device (e.g., a processor, client, or server, etc.).

FIG. 7 is a block diagram of an electronic device according to an exemplary embodiment of the present disclosure.

Referring to FIG. 7, an electronic device 700 includes at least one memory 701 and at least one processor 702, the at least one memory 701 stores a computer-executable instruction set, when the computer-executable instruction set is executed by the at least one processor 702, a file processing method applied to an EDA tool according to an exemplary embodiment of the present disclosure is performed.

As an example, the electronic device 700 may be a PC computer, a tablet apparatus, a personal digital assistant, a smart phone, or any other apparatus capable of executing the above instruction set. As described herein, the electronic device 700 may not be a single electronic device, but may also be any set of apparatuses or circuits capable of executing the instructions (or instruction set) described with reference to the present disclosure individually or jointly. In some cases, the electronic device 700 may be part of an integrated control system or system manager. Additionally or alternatively, the electronic device 700 may be configured as a portable electronic device that interfaces locally or remotely (e.g., via wireless transmission).

Referring to electronic device 700, the processor 702 may include central processing units (CPUs), graphics processing units (GPUs), programmable logic apparatuses, special purpose processor systems, microcontrollers or microprocessors. Additionally, by way of example and not limitation, the processor may include analog processors, digital processors, microprocessors, multi-core processors, processor arrays, network processors, etc.

The processor 702 may execute instructions or code stored in the memory 701. In some cases, memory 701 may be configured to store data. Instructions and data may also be transmitted and received over a network via a network interface apparatus, which may employ any known transport protocol.

The memory 701 may be integrated with the processor 702, e.g., a RAM or flash memory is arranged within an integrated circuit microprocessor or the like. Additionally, the memory 701 may include a separate apparatus such as an external disk drive, storage array, or any other storage device that may be used by a database system. The memory 701 and the processor 702 may be operatively coupled, or may communicate with each other, e.g., through I/O ports, network connections, etc., to enable the processor 702 to read files stored in the memory 701.

Additionally, the electronic device 700 may also include a video display (such as a liquid crystal display) and a user interaction interface (such as a keyboard, mouse, touch input device, etc.). In some examples, components of electronic device 700 may be connected to each other via a bus and/or network.

Additionally, according to an exemplary embodiment of the present disclosure, there may be provided a computer readable storage medium storing instructions, wherein the instructions, when run by at least one computing apparatus, cause the at least one computing apparatus to perform a file processing method applied to an EDA tool as described herein.

Examples of computer readable storage media herein include: Read Only Memory (ROM), Random Access Programmable Read Only Memory (RAPROM), Electrically Erasable Programmable Read Only Memory (EEPROM), Random Access Memory (RAM), Dynamic Random Access Memory (DRAM), Static Random Access Memory (SRAM), flash memory, non-volatile memory, CD-ROM, CD-R, CD+R, CD-RW, CD+RW, DVD-ROM, DVD-R, DVD+R, DVD-RW, DVD+RW, DVD-RAM, BD-ROM, BD-R, BD-R LTH, BD-RE, Blue-ray or optical disk storage, Hard Disk Drive (HDD), Solid State Drive (SSD), card storage (such as multimedia cards, secure digital (SD) cards or extremely fast digital (XD) cards), magnetic tapes, floppy disks, magneto-optical data storage devices, optical data storage devices, hard disks, solid state disks, and any other devices that are configured to store computer programs and any associated data, data files and data structures in a non-transitory manner and provide the computer programs and any associated data, data files and data structures to a processor or computer so that the processor or computer may execute the computer programs.

The instructions or computer programs in the computer readable storage medium described herein may be executed in an environment deployed in a computer device, such as client, host, proxy device, server, etc. Additionally, in an example, the computer programs and any associated data, data files, and data structures may be distributed on a networked computer system, such that the computer programs and any associated data, data files, and data structures are stored, accessed, and executed through one or more processors or computers in a distributed manner. Note that the instructions may also be used to perform steps in addition to the steps described herein or to perform more specific processing when performing the steps described herein. Additionally, the content of the steps and further processing may already have been referred to in the process of describing the relevant methods, and will therefore not be repeated herein in order to avoid repetition.

An embodiment of the present disclosure includes a system comprising at least one computing apparatus and at least one storage apparatus storing instructions, wherein the instructions, when run by the at least one computing apparatus, cause the at least one computing apparatus to perform a file processing method applied to an EDA tool as described herein.

It should be noted that a system according to the exemplary embodiment of the present disclosure may rely entirely on operation of a computer program or instructions to implement the corresponding functions, i.e., the individual units correspond to the steps in the functional architecture of the computer program, such that the entire system is invoked to implement the corresponding functions by means of specialized software packages (e.g., libraries).

Additionally or alternatively, when the system described herein is implemented as software, firmware, middleware, or microcode, program code or code segments for performing the corresponding operations may be stored in a computer readable medium, such as a storage medium, such that at least one processor or at least one computing apparatus may perform corresponding operations by reading and running the corresponding program code or code segments.

According to an exemplary embodiment of the present disclosure, a storage apparatus may be integrated with a computing apparatus, e.g., RAM or a flash memory is deployed in an integrated circuit microprocessor, etc. Additionally, the storage apparatus may include a separate apparatus, such as an external disk drive, a storage array, or any other storage apparatus that may be used by a database system. The storage apparatus and the computing apparatus may be operationally coupled or may communicate with each other, for example, via I/O ports, network connection, and the like, such that the computing apparatus is capable of reading instructions stored in the storage apparatus.

The file processing method and apparatus applied to an EDA tool, the storage medium, the electronic device, and the system provided by the present disclosure enable the EDA tool to no longer directly process an IP-XACT XML file, but to process a lightweight JSON file, such that when there are a large number of IP-XACT XML files in the EDA tool, the negative impact on the performance of the EDA tool due to the fact that processing these files may occupy a lot of memory and CPU resources is avoided.

Additionally, comparing a JSON object with an XML DOM object when each of the JSON object and the XML DOM object contain the same semantic information, the JSON object may occupy significantly less memory resources than the XML DOM object. Therefore, accessing and maintaining content of the JSON object is simpler and more flexible than the XML DOM.

Additionally, the predefined conversion rule may be used to easily and quickly convert an IP-XACT file in JSON format and an IP-XACT file in XML format.

The above describes various exemplary embodiments of the present disclosure, and it should be understood that the above description is only exemplary and not exhaustive, and the present disclosure is not limited to the disclosed exemplary embodiments. Without departing from the scope and spirit of the present disclosure, many modifications and changes will be apparent to a person of ordinary skill in the art. Therefore, the scope of protection of the present disclosure should be based on the scope of the claims.

What is claimed is:

1. A method of electronic circuit design, the method comprising:
obtaining a first electronic circuit design file, wherein the first electronic circuit design file has an XML format;
converting the first electronic circuit design file to a second electronic circuit design file having a JSON format based on a conversion rule associating a first XML tag corresponding to an electronic circuit design element with a JSON attribute corresponding to the same electronic circuit design element; and
generating, using an electronic design automation (EDA) tool, an electronic circuit design based on the second electronic circuit design file.

2. The method of claim 1, wherein generating the electronic circuit design comprises:
performing a parsing operation on the second electronic circuit design file to generate a JSON object; and
performing an operation on the JSON object, wherein the operation comprises at least one of creating, traversing, adding, deleting, and modifying.

3. The method of claim 2, wherein generating the electronic circuit design comprises:
serializing the object to obtain a serialized electronic circuit design file; and
saving the serialized electronic circuit design file.

4. The method of claim 1, wherein converting the first electronic circuit design file to the second electronic circuit design file comprises:
validating the first electronic circuit design file;
parsing the validated first electronic circuit design file;
converting, based on the conversion rule, the first electronic circuit design file to obtain a JSON object; and
serializing the JSON object to obtain the second electronic circuit design file.

5. The method of claim 1, further comprising:
validating the second electronic circuit design file;
parsing the validated second electronic circuit design file;
converting, based on the conversion rule, the second electronic circuit design file to obtain an XML object; and
serializing the XML object to obtain a third electronic circuit design file.

6. The method of claim 1, wherein the conversion rule maintains semantic consistency.

7. The method of claim 1, wherein generating the electronic circuit design comprises:
verifying a validity of the first electronic circuit design file based on a predetermined validation module,
wherein the predetermined validation module comprises a predefined rule and a predefined constraint, each of the predefined rule and constraint being specific to the first electronic circuit design file.

8. An apparatus for electronic circuit design, the apparatus comprising:
a file acquisition module configured to obtain a first electronic circuit design file; wherein the first electronic circuit design file has an XML format;
a conversion module configured to convert the first electronic circuit design file to a second electronic circuit design file having a JSON format based on a conversion rule associating a first XML tag corresponding to an electronic circuit design element with a JSON attribute corresponding to the same electronic circuit design element; and
a file process module configured to generate an electronic circuit design based on the second electronic circuit design file.

9. The apparatus of claim 8, wherein the file process module is configured to:
perform a parsing operation on the second electronic circuit design file to generate a JSON object; and
perform an operation on the JSON object, wherein the operation comprises at least one of creating, traversing, adding, deleting, and modifying.

10. The apparatus of claim 9, wherein the file process module is further configured to:
serialize the object to obtain a serialized electronic circuit design file; and
save the serialized electronic circuit design file.

11. The apparatus of claim 8, wherein the conversion module is further configured to:
validate the first electronic circuit design file;
parse the validated first electronic circuit design file;
convert, based on the conversion rule, the first electronic circuit design file to obtain a JSON object; and
serialize the JSON object to obtain the second electronic circuit design file.

12. The apparatus of claim 8, wherein the conversion module is further configured to:
validate the second electronic circuit design file;
parse the validated second electronic circuit design file;
convert, based on the conversion rule, the second electronic circuit design file to obtain an XML object; and
serialize the XML object to obtain a third electronic circuit design file.

13. The apparatus of claim 8, wherein the conversion rule maintains semantic consistency.

14. The apparatus of claim 8, wherein the file process module is further configured to:
verify a validity of the first electronic circuit design file based on a predetermined validation module;
wherein the predetermined validation module comprises a predefined rule and a predefined constraint, each of the predefined rule and constraint being specific to the first electronic circuit design file.

15. An electronic device comprising:
at least one processor;
at least one memory storing computer-executable instructions,
wherein the computer-executable instructions, when run by the at least one processor, cause the at least one processor to perform a file processing method applied to an EDA tool according to claim 1.

16. A computer readable storage medium storing instructions, wherein the instructions, when run by at least one computing apparatus, cause the at least one computing apparatus to perform a file processing method applied to an EDA tool according to claim 1.

17. A system comprising at least one computing apparatus and at least one storage apparatus storing instructions, wherein the instructions, when run by the at least one computing apparatus, cause the at least one computing apparatus to perform a file processing method applied to an EDA tool according to claim 1.
